(19) United States
(12) Patent Application Publication
(10) Pub. No.: US 2019/0320541 A1
(43) Pub. Date: Oct. 17, 2019

(54) MOUNTING APPARATUS WITH BUBBLE REMOVAL MECHANISM

(71) Applicant: Quirklogic, Inc., Calgary (CA)

(72) Inventors: Alfonso Fabian de la Fuente, Victoria (CA); Michael Howatt Mabey, Calgary (CA)

(21) Appl. No.: 16/380,656

(22) Filed: Apr. 10, 2019

Related U.S. Application Data
(60) Provisional application No. 62/656,317, filed on Apr. 11, 2018.

(51) Int. Cl. H05K 5/02

(52) U.S. Cl. CPC H05K 5/0204

(57) ABSTRACT

Mounting apparatuses and systems including mounting apparatuses and electronic devices. The mounting apparatus may include a flexible pad comprising a back surface coated with a removable and reusable adhesive and a front surface; a backing patch affixed to the front surface of the flexible pad; and a coupler affixed to and extending outwardly from the backing patch.

### CROSS REFERENCE TO RELATED APPLICATIONS

This patent application claims the benefit of U.S. Provisional Patent Application Ser. No. 62/656,317 filed on Apr. 11, 2018 under 35 U.S.C. § 119(e). U.S. Provisional Patent Application Ser. No. 62/656,317 is incorporated herein by reference in its entirety.

### BACKGROUND

Mounting solutions for electronic devices, and other objects, are commonplace. Some are permanent solutions, while others are temporary.

### SUMMARY

In general, in one aspect, embodiments of the invention relate to a mounting apparatus. The apparatus may include a flexible pad comprising a back surface coated with a removable and reusable adhesive and a front surface; a backing patch affixed to the front surface of the flexible pad; and a coupler affixed to and extending outwardly from the backing patch.

In general, in one aspect, embodiments of the invention relate to a mounting apparatus. The apparatus may include a flexible pad comprising a pin perforation and an adhesive gel pad disposed on a back surface of the flexible pad; and a hollow pin configured to pierce through the flexible pad at the pin perforation.

In general, in one aspect, embodiments of the invention relate to a system.

The system may include an electronic device; and at least one mounting apparatus operatively connected to the electronic device. The mounting apparatus may include a flexible pad comprising a back surface coated with a removable and reusable adhesive, and a front surface coated with a permanent adhesive.

Other aspects of the invention will be apparent from the following description and the appended claims.

### BRIEF DESCRIPTION OF DRAWINGS

FIGS. 1A and 1B show front and side views of an oval mounting apparatus in accordance with one or more embodiments of the invention.

FIGS. 2A and 2B show front and side views of a rounded quadrilateral mounting apparatus in accordance with one or more embodiments of the invention.

FIGS. 3A and 3B show front and side views of a bubble removal mechanism in accordance with one or more embodiments of the invention.

FIGS. 4A and 4B show alternative removal mechanisms in accordance with one or more embodiments of the invention.

FIGS. 5A-5C show a push pin assisted mounting apparatus in accordance with one or more embodiments of the invention.

FIGS. 6A-6D show a universal clevis based mounting apparatus in accordance with one or more embodiments of the invention.

FIGS. 7A-7C show a push pin in accordance with one or more embodiments of the invention.

FIGS. 7D-7H show a push pin assisted bubble removal mechanism in accordance with one or more embodiments of the invention.

FIGS. 8A-8D show a push pin assisted bubble removal mechanism in accordance with one or more embodiments of the invention.

FIGS. 9A-9C show a push pin assisted mounting apparatus in accordance with one or more embodiments of the invention.

FIGS. 10A-10D show a plate assisted mounting apparatus in accordance with one or more embodiments of the invention.

FIGS. 11A-11D show side views of a hollow pin assisted mounting apparatus in accordance with one or more embodiments of the invention.

FIGS. 12A and 12B show a pivoting mounting apparatus in accordance with one or more embodiments of the invention.

FIGS. 13A and 13B show a pivoting mounting apparatus in accordance with one or more embodiments of the invention.

FIG. 14 shows an air injected removal mechanism in accordance with one or more embodiments of the invention.

### DETAILED DESCRIPTION

Specific embodiments of the invention will now be described in detail with reference to the accompanying figures. In the following detailed description of the embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

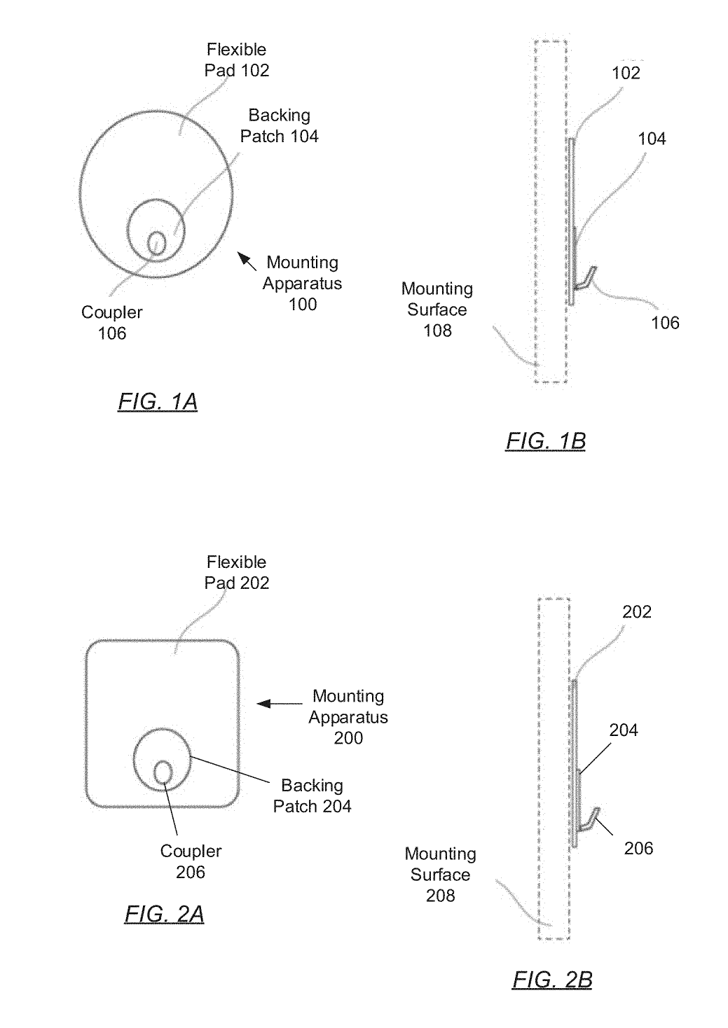

In the following description of FIGS. 1A-14, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment which may be implemented in addition to, in conjunction with, or in place of the embodiments described with regard to a corresponding like-named component in any other figure.

Throughout the application, ordinal numbers (e.g., first, second, third, etc.)

may be used as an adjective for an element (i.e., any noun in the application). The use of ordinal numbers is not to necessarily imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and a first element may encompass more than one element and succeed (or precede) the second element in an ordering of elements.

In general, embodiments of the invention relate to removing mounting apparatuses off mounting surfaces using air or vacuum bubbles. Specifically, one or more embodiments of the invention entails a mounting apparatus including a coupler, which when force is exerted thereon, a vacuum bubble forms at the interface between the mounting apparatus and a mounting surface, thus, facilitating the removal of the mounting apparatus therefrom. In one or more other embodiments of the invention, the mounting apparatus may alternatively entail the channeled introduction (or forced injection) of air towards the aforementioned interface, thus further facilitating the removal of the mounting apparatus from the mounting surface. In one or more additional embodiments of the invention, the mounting apparatus includes a removable push pin, which may be inserted through the mounting apparatus and anchors to the mounting surface, thus, further securing the mounting apparatus to the mounting surface. When extracted, the push pin may catch and deform the mounting apparatus, thereby creating a pocket at the aforementioned interface, thus, also forming an air and/or vacuum bubble that facilitates the removal of the mounting apparatus from the mounting surface.

FIGS. 1A and 1B show front and side views of an oval mounting apparatus in accordance with one or more embodiments of the invention. The mounting apparatus (100) may be a physical device through which an electronic device (not shown) may be secured to a mounting surface (108) (e.g., a wall). The mounting apparatus (100) may include a flexible pad (102), a backing patch (104), and a coupler (106). Each of these components is described below.

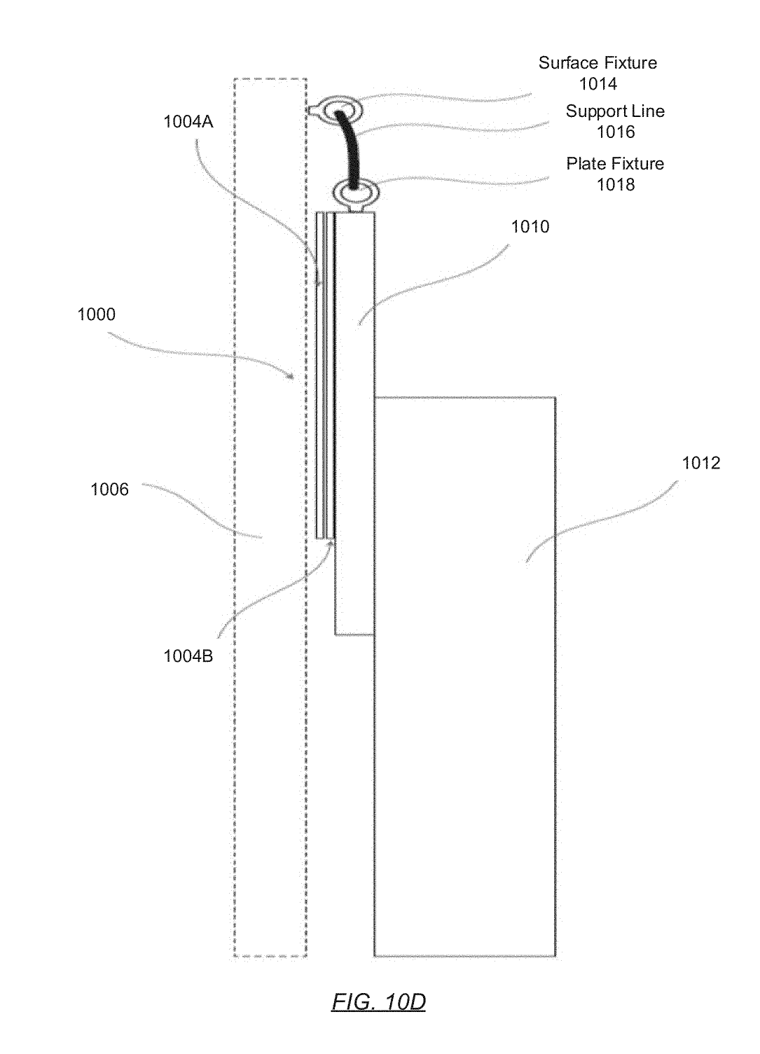

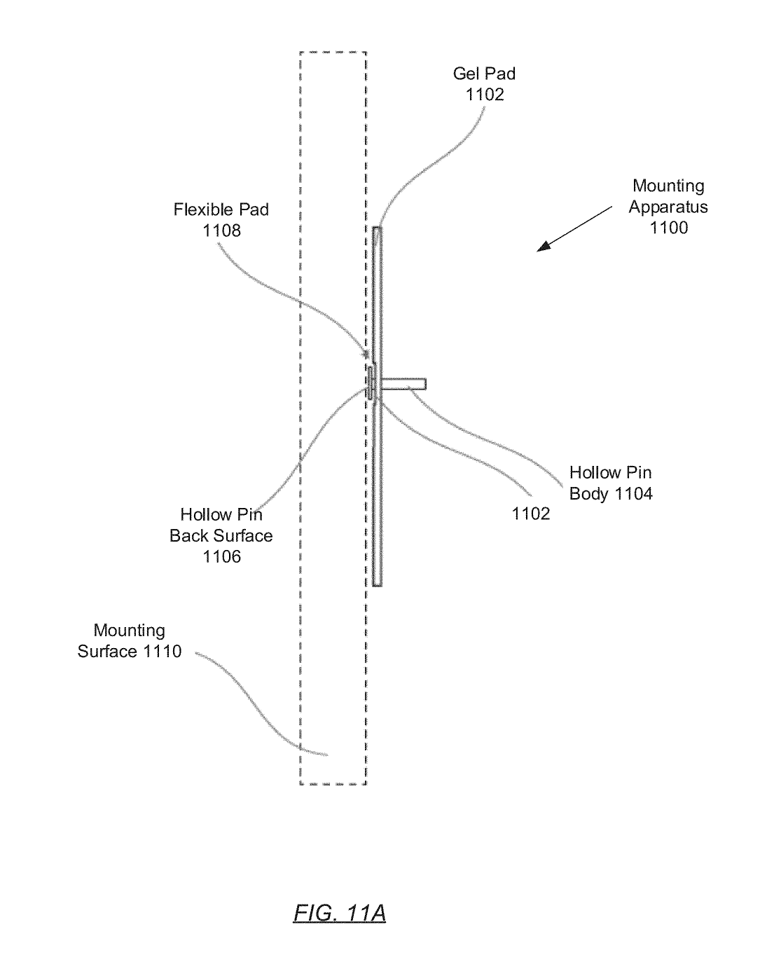

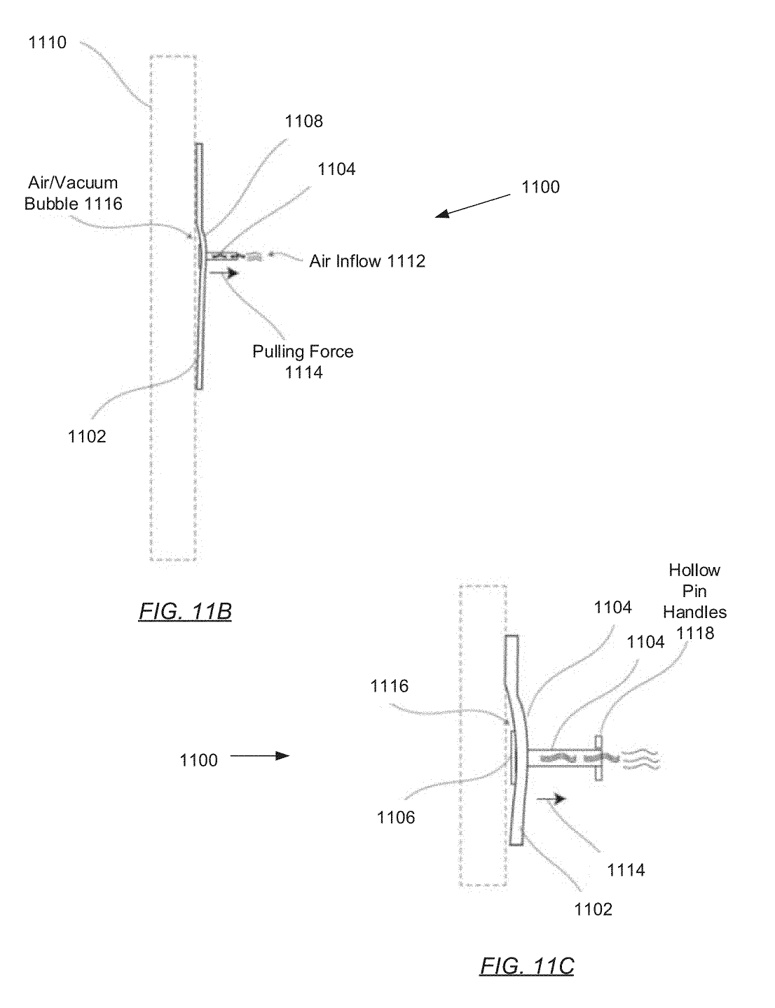

In one embodiment of the invention, the flexible pad (102) may be a pliable and light-weight, yet durable and tear-resistant sheet of material. Examples of said material include, but are not limited to: films (e.g., polyester, polyethylene, polyurethane, polypropylene, polytetrafluorethylene (PTFE), vinyl, etc.), foams (e.g., acrylic, polyethylene, urethane, neoprene, etc.), foils (e.g., aluminum, copper, lead, stainless steel, etc.), cloths (e.g., cotton, polyester, acetate, nylon, rayon, etc.), rubbers (e.g., silicone, neoprene, ethylene propylene diene monomer (EPDM), other natural and/or synthetic elastomers, etc.), or a combination thereof The flexible pad (102) may include a back surface (not shown) coated with a removable and/or reusable pressure-sensitive acrylic, rubber, or silicone-based adhesive. The removable and/or reusable adhesive may facilitate the temporary attachment of the flexible pad (102), and thus the mounting apparatus (100), to the mounting surface (108). Further, in one embodiment of the invention, the flexible pad (102) may include an uncoated front surface (as is the case for embodiments of the mounting apparatus (100) shown in FIGS. 1A and 1B. In another embodiment of the invention, the front surface of the flexible pad (102) may alternatively be coated with a temporary or permanent pressure-sensitive acrylic, rubber, or silicone-based adhesive whereon additional components (e.g., a device mounting plate) and/or an electronic device may be adhered (see e.g., FIGS. 9C and 10B-10D).

In one embodiment of the invention, the backing patch (104) may represent backing material for supporting the affixture of the coupler (106) to the flexible pad (102). The backing patch (104) may be composed of materials including, but not limited to: thermoset plastics (e.g., polyurethanes, polyesters, epoxy resins, phenolic resins, etc.), thermoplastics (polyethylene (PE), polypropylene (PP), polyvinyl chloride (PVC), etc.), other organic polymers, or a combination thereof The backing patch (104) itself may be affixed to the front surface of the flexible pad (102) through, for example, a permanent adhesive.

In one embodiment of the invention, the coupler (106) may be a protrusion affixed to, and extending outwardly from, the backing patch (104). The coupler (106) may be designed to mate with a coupler receptacle embedded within the back surface of an electronic device (not shown). In one embodiment of the invention, the coupler (106) may be constructed of similar materials as the backing patch (104). In another embodiment of the invention, the coupler (106) may be constructed of metallic materials (e.g., steel, brass, nickel, etc.). Furthermore, examples of the coupler (106) include, but are not limited to: an anchor, a toggle, a connector, an adapter, a magnet, a hook, a pin, a plug, and a bracket.

FIGS. 2A and 2B show front and side views of a rounded quadrilateral mounting apparatus in accordance with one or more embodiments of the invention. The various components depicted in FIGS. 2A and 2B may be substantially similar to the various components described above with respect to FIGS. 1A and 1B. The rounded quadrilateral shape of the flexible pad (202) is meant to substantively show that the flexible pad (202) may contour any two-dimensional shape that may include rounded edges. The rounded edges impede the unintentional removal of the flexible pad (202), and thus the mounting apparatus (200), from any mounting surface (208) to which the mounting apparatus (200) may be adhered. Those skilled in the art will appreciate that the invention is not limited to flexible pads that include rounded edges.

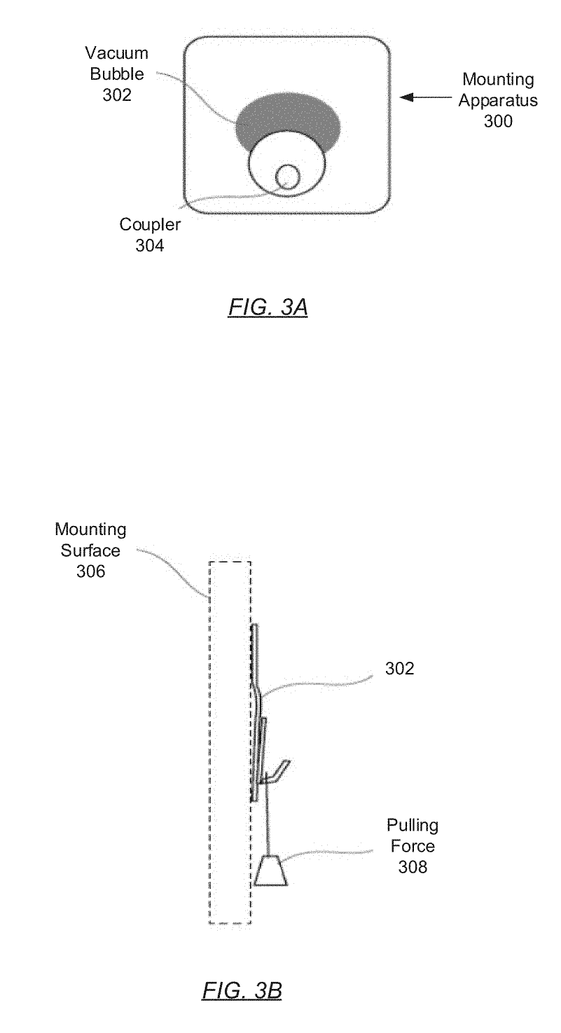

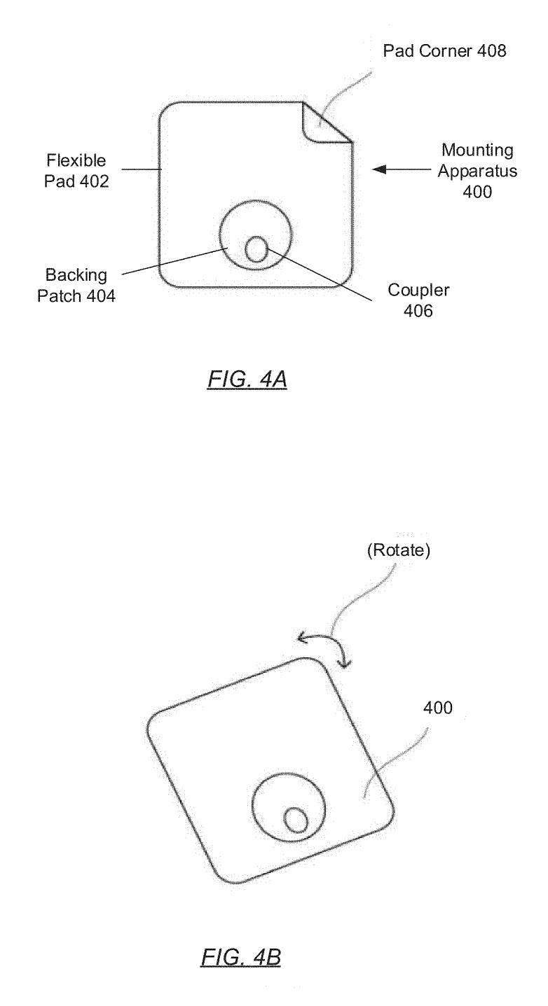

FIGS. 3A and 3B show front and side views of a bubble removal mechanism in accordance with one or more embodiments of the invention. Specifically, upon the exertion of an outward and/or downward pulling force (308) on the coupler (304), an air or vacuum bubble (302) may form at the interface between the back surface of the mounting apparatus (300) (or more specifically, the back surface of the flexible pad) and the mounting surface (306) to which the mounting apparatus (300) may be adhered. In order for the air or vacuum bubble (302) to form, however, the exerted pulling force (308) may need to exceed a rated size-to-weight ratio for the removable and/or reusable adhesive (not shown) coated onto the back surface of the flexible pad. Moreover, the formation of the air or vacuum bubble (302) subsequently facilitates the removal of the mounting apparatus (300) from the mounting surface (306) by reducing the surface area to which the removable and/or reusable adhesive interfaces with the mounting surface (306).

FIGS. 4A and 4B show alternative removal mechanisms in accordance with one or more embodiments of the invention. Specifically, in one embodiment of the invention and as depicted in FIG. 4A, a mounting apparatus (400) may also be removed from any mounting surface (not shown) through the peeling off of the flexible pad (402) at one or more of its rounded pad corners (408). In another embodiment of the invention and as depicted in FIG. 4B, the mounting apparatus (400) may be removed from a mounting surface by way of tilting or rotating the flexible pad (402) towards an orientation perpendicular to an initial orientation at which the flexible pad (402) had been adhered to the mounting surface.

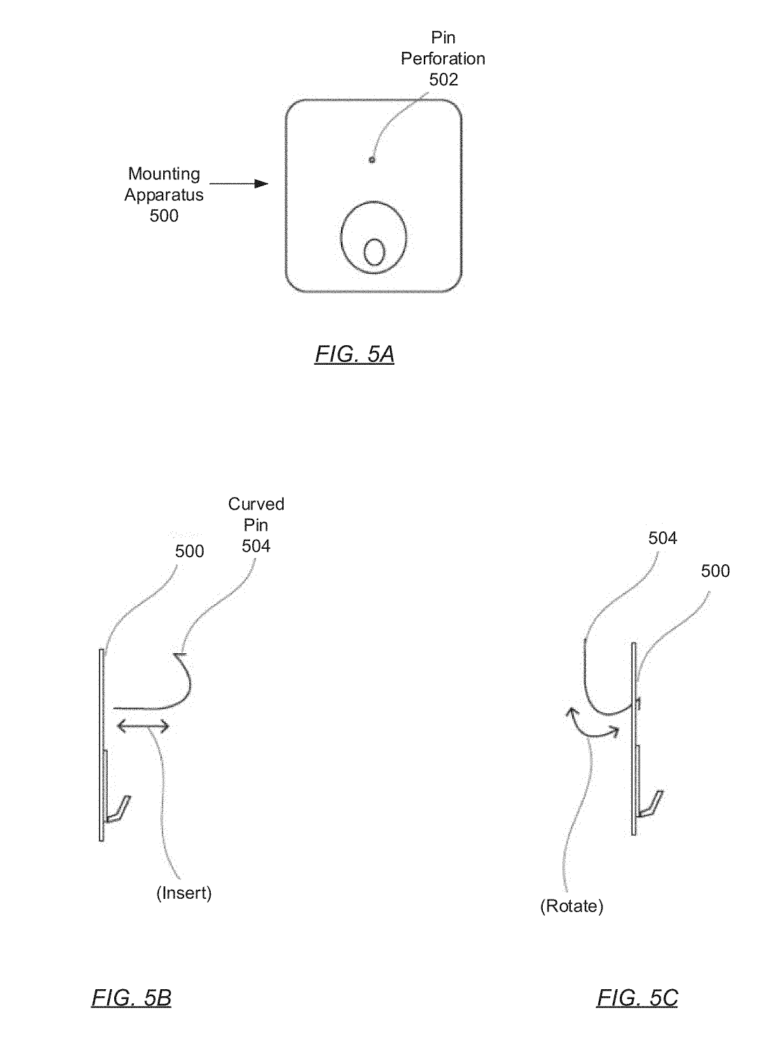

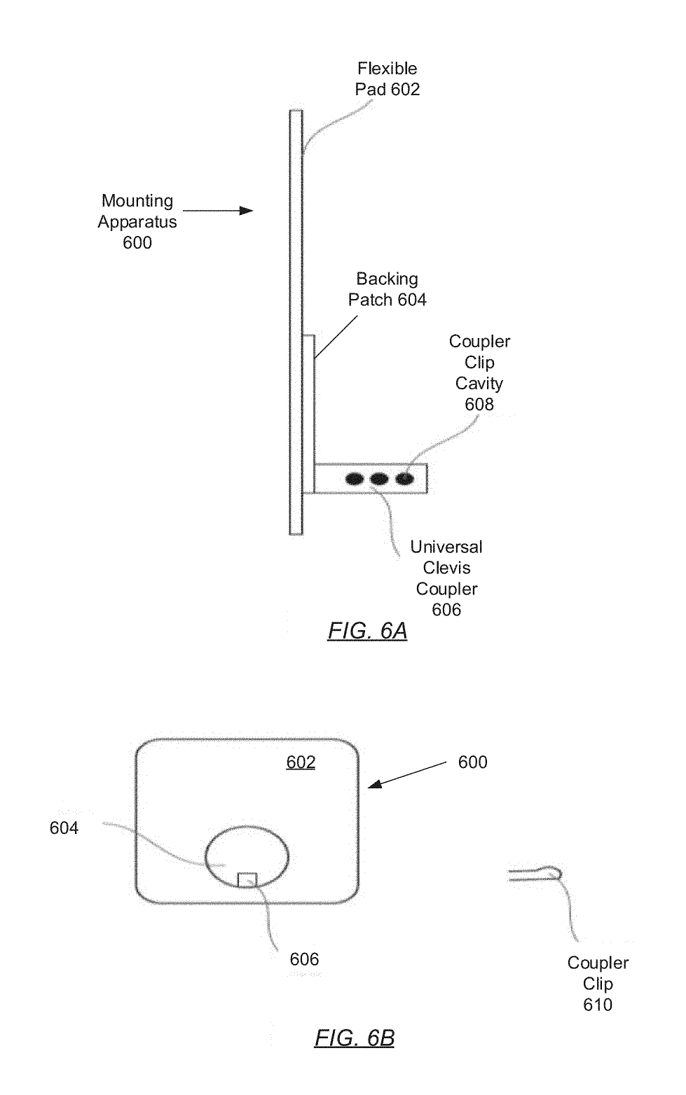

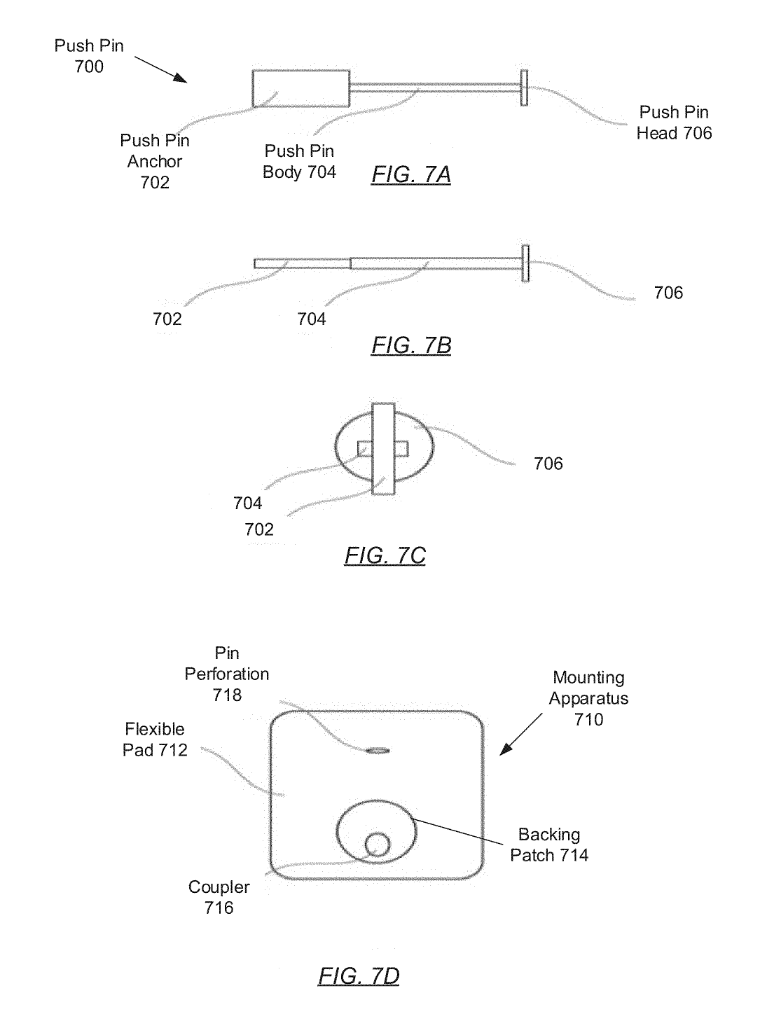

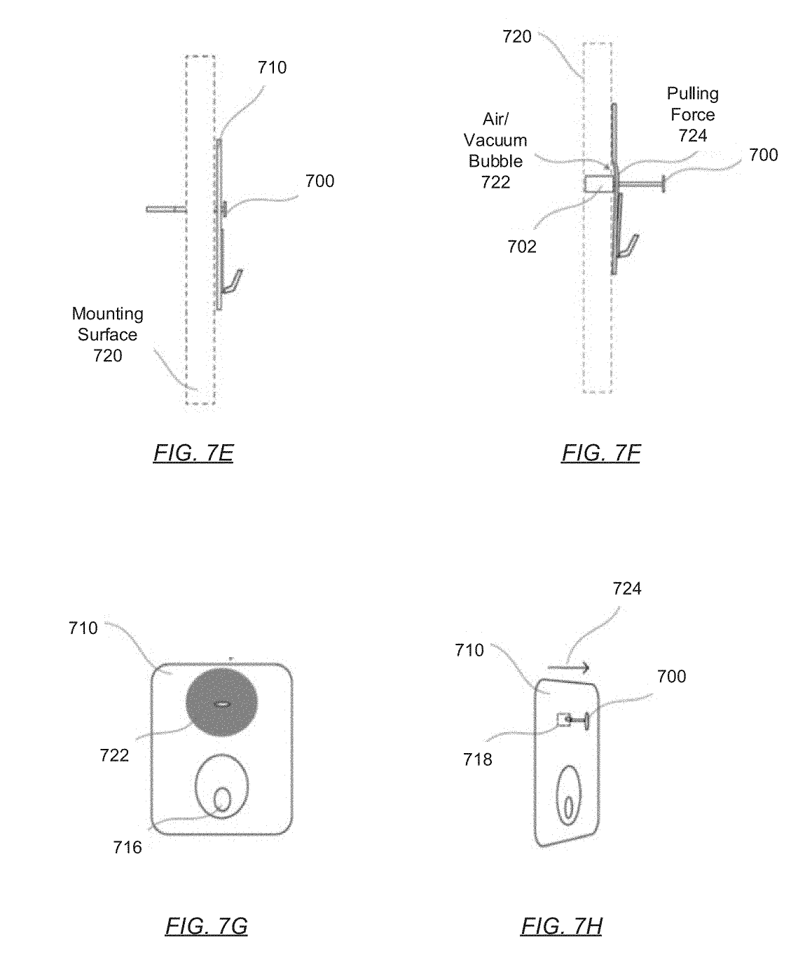

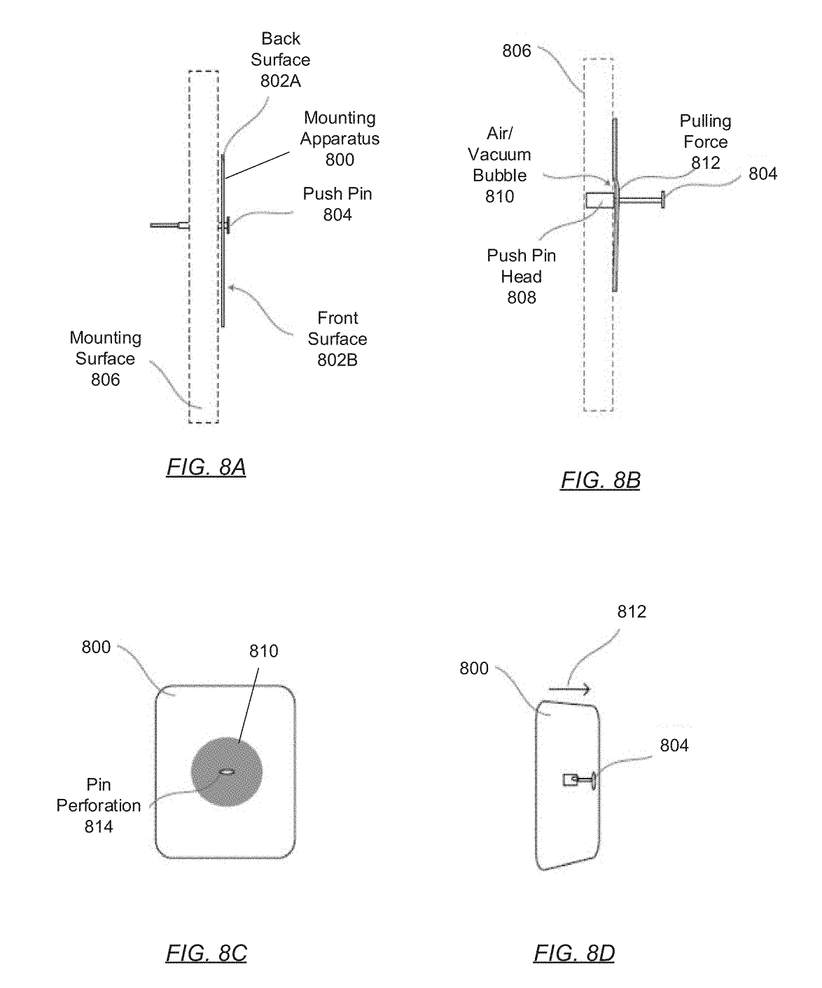

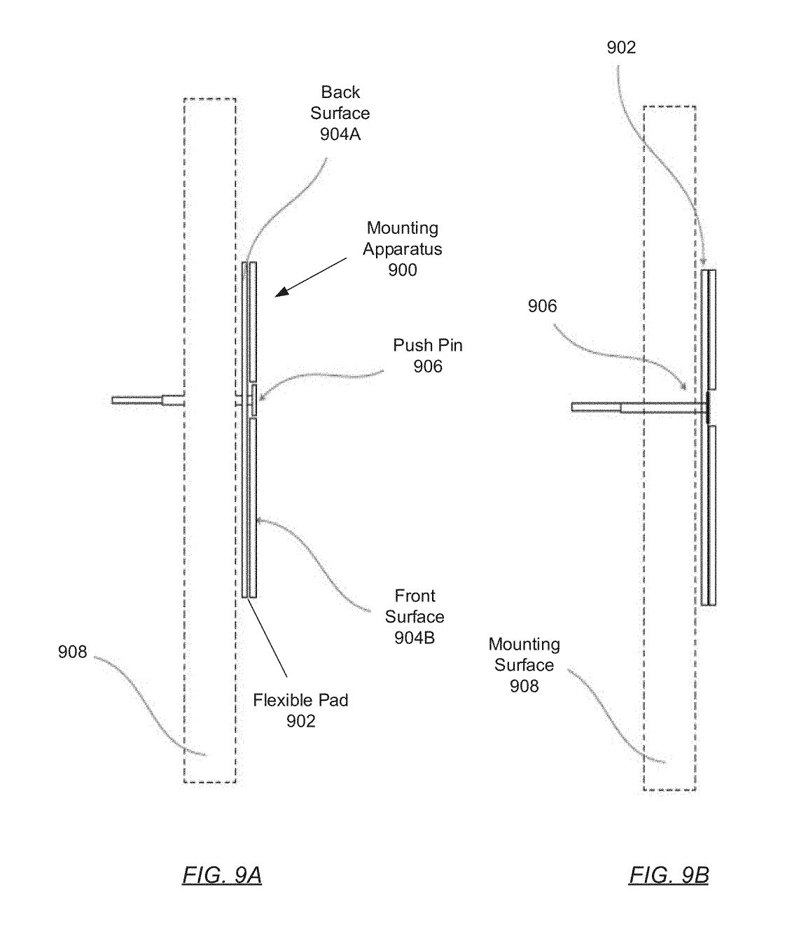

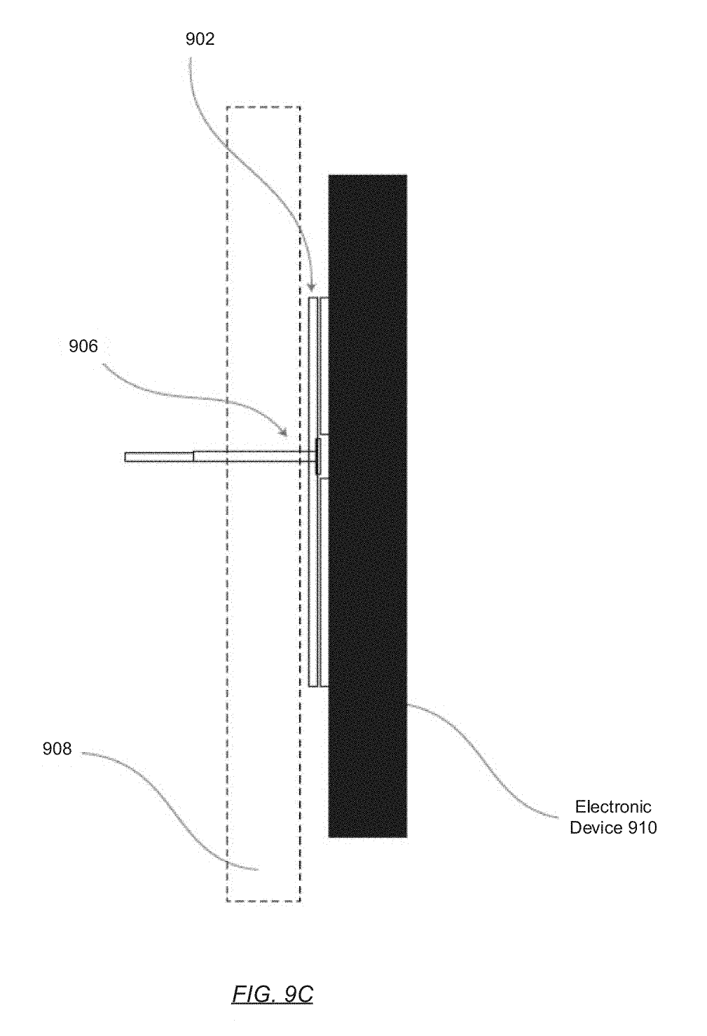

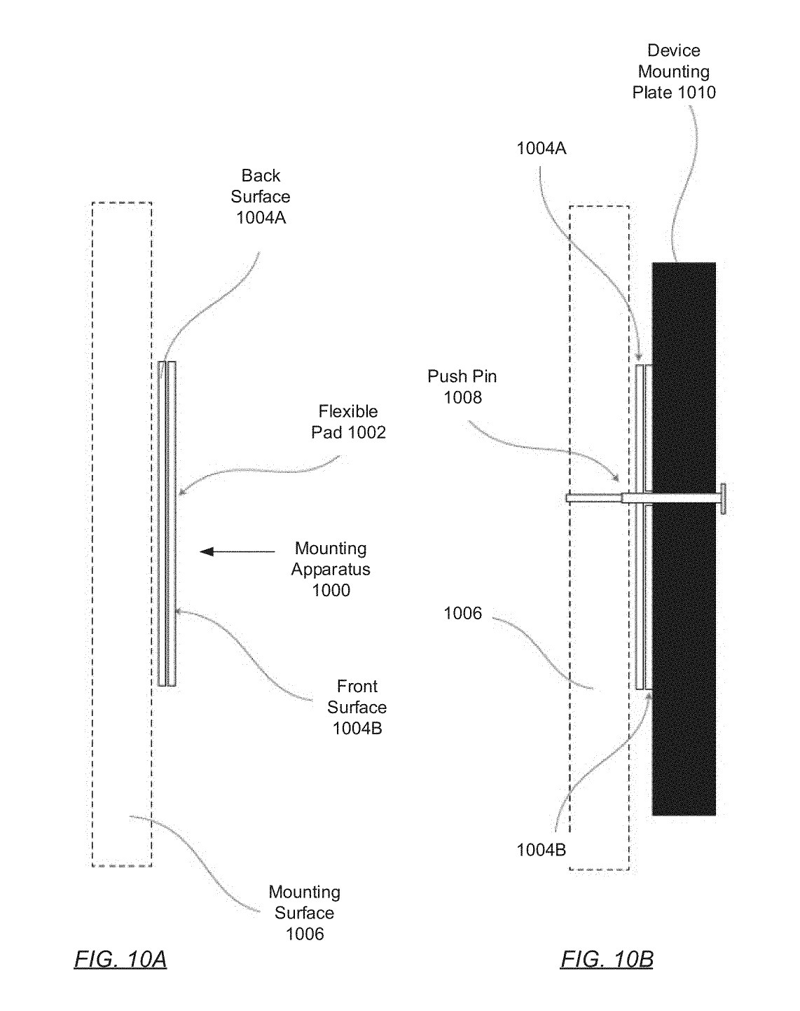

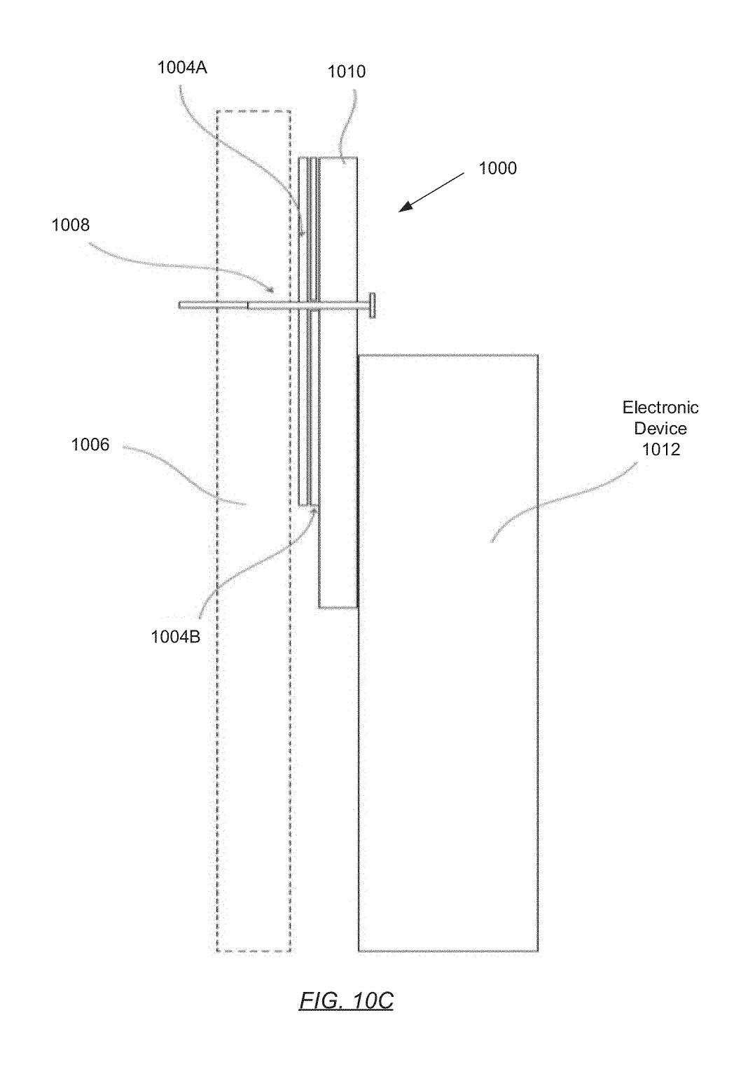

FIGS. 5A-5C show a push pin assisted mounting apparatus in accordance with one or more embodiments of the invention. The mounting apparatus (500) may include a pin perforation (502) (e.g., a through-hole) through which a curved pin (504), or alternatively, a push pin (see e.g., FIGS. 7A-8D), pierces the flexible pad of the mounting apparatus (500). Therefrom, the curved pin (504) or push pin (not shown), when inserted through the pin perforation (502), may further secure the mounting apparatus (500) to a mounting surface (not shown).

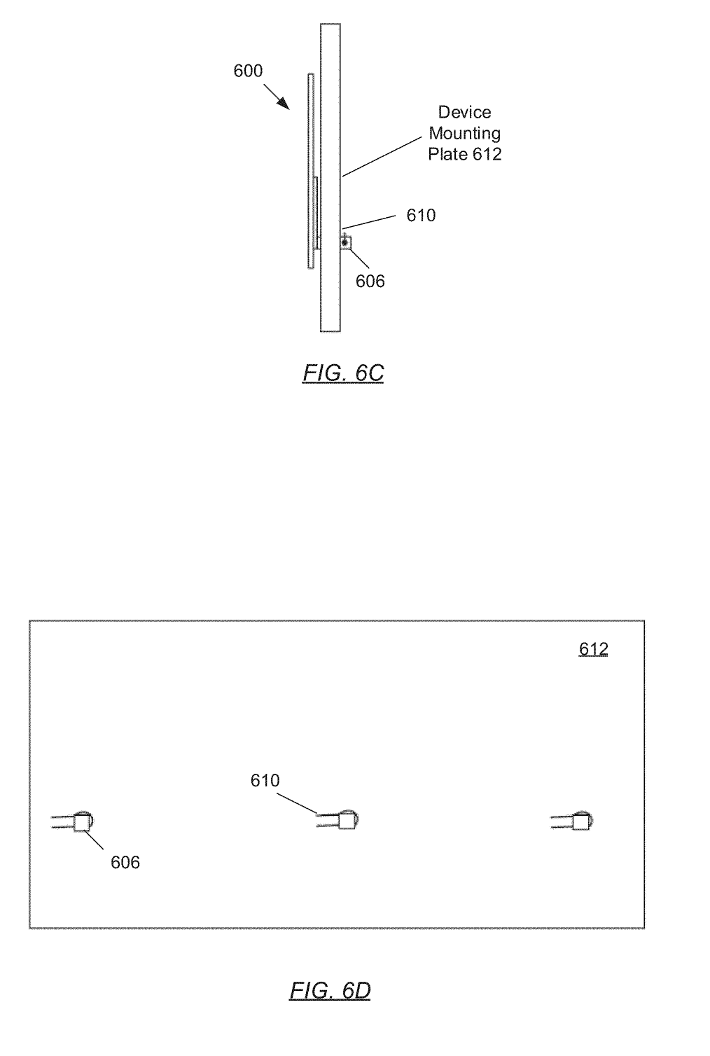

FIGS. 6A-6D show a universal clevis based mounting apparatus in accordance with one or more embodiments of the invention. A universal clevis based mounting apparatus (600) may include a universal clevis coupler (606), which is affixed to, and extends outwardly from, the backing patch (604). The universal clevis coupler (606) may include multiple coupler clip cavities (608) disposed along the length of the universal clevis coupler (606). The universal clevis based mounting apparatus (600) may further include a coupler clip (610) (e.g., a cotter pin) that may be fastened through any one of the multiple coupler clip cavities (608) to fasten an attachment (e.g., a device mounting plate (612)) thereon.

In one embodiment of the invention, the above-mentioned device mounting plate (612) may be a device on which an electronic device (not shown) may be directly mounted (rather than being directly hung from or coupled to the coupler (606)). The device mounting plate (612) may include one or more through-holes (not shown) through which one or more universal clevis couplers (606) may pass. Thereafter, the device mounting plate (612) may be secured thereon by fastening respective coupler clips (610) to each universal clevis coupler (606) on which the device mounting plate (612) resides.

FIGS. 7A-7C show a push pin in accordance with one or more embodiments of the invention. The push pin (700) may be a device for further fastening a mounting apparatus (710) to a mounting surface (not shown). The push pin (700) may include a push pin anchor (702) coupled to a push pin body (704), which in turn may be coupled to a push pin head (706). These aforementioned components may be manufactured as a single, contiguous component, or may alternatively be manufactured as two or more separate components, which are then fused together through adhesion, welding, or other coupling methods.

In one embodiment of the invention, the push pin anchor (702) may be a flat-bladed piece of metal (e.g., stainless steel, brass, tin, iron, etc.) or plastic (e.g., thermoplastics, thermoset plastics, etc.) designed to pierce a mounting surface (not shown) when the push pin (700) is thrusted therein by a user. The push pin anchor (702) may be the portion of the push pin (700) that may further secure the mounting apparatus (not shown) to the mounting surface. The push pin anchor (702) may be disposed at one end of the push pin body (704). In one embodiment of the invention, the push pin body (704) may be a cylindrical piece of metal or plastic of any pre-specified length. Disposed at the other end of the push pin body (704) lies the push pin head (706). In one embodiment of the invention, the push pin head (706) may represent a handle through which the push pin (700) may be manipulated. The push pin head (706) may generally be wide in order to distribute the pushing force exerted on the push pin (700) when thrusted into a mounting surface through the flexible pad (not shown), as well as to facilitate the withdrawal of the push pin (700) from the mounting surface. The push pin head (706) may be flat, domed, spherical, cylindrical, or any other shape.

FIGS. 7D-7H show a push pin assisted bubble removal mechanism in accordance with one or more embodiments of the invention. The mounting apparatus (710), as described above, may include a pin perforation (718) through which a push pin (700) may be inserted to supplement the fastening of the mounting apparatus (710) to a mounting surface (720). The push pin (700) may further include functionality to, when withdrawn from the mounting surface (720), cause the formation of an air or vacuum bubble (722) at the interface between the mounting surface (720) and the flexible pad (712). In order to achieve this, the push pin (700), however, must be withdrawn at an orientation perpendicular to the initial orientation at which the push pin (700) had been inserted into the mounting surface (720). When at an orientation different from the initial orientation, the push pin anchor (702) catches and deforms a portion of the flexible pad (712) during the extraction process. The deformation of the flexible pad (712) substantively creates a pocket wherein air (from behind the mounting surface (720)) may accumulate, thereby forming an air bubble (722). The formation of the air or vacuum bubble (722), as described above, subsequently facilitates the removal of the mounting apparatus (710) from the mounting surface (720) by reducing the surface area to which the flexible pad (712) (i.e., removable and/or reusable adhesive) interfaces with the mounting surface (720).

FIGS. 8A-8D show a push pin assisted bubble removal mechanism in accordance with one or more embodiments of the invention. The mounting apparatus (800) illustrated herein exclude the backing patch and coupler. Notwithstanding, however, the remaining components of the mounting apparatus (800) and the push pin assisted bubble removal mechanism depicted in FIGS. 8A-8D are substantially similar to embodiments of the invention disclosed in FIGS. 7D-7H.

FIGS. 9A-9C show a push pin assisted mounting apparatus in accordance with one or more embodiments of the invention. The mounting apparatus (900) includes two surfaces—a back surface (904A) facing the mounting surface (908) and a front surface (904B), which would face an attachment (e.g., a device mounting plate (see e.g., 1010 in FIG. 10B)) or an electronic device (910). As described above, the back surface (904A) of the flexible pad (902) may be coated with a removable and/or reusable adhesive (not shown), thereby allowing for error-proneness during the mounting apparatus (900) installation process. Further, the front surface (904B) of the flexible pad (902) may alternatively be coated with a permanent adhesive (not shown) to firmly secure an attachment or electronic device (910) thereto. Moreover, a push pin (906) may be inserted (at a pin perforation (not shown) on the flexible pad (902)), which would pierce the flexible pad (902) and the mounting surface (908) disposed beneath, thereby, further securing the flexible pad (902) to the mounting surface (908). After the push pin (906) is firmly installed, the attachment (not shown) or electronic device (910) may be adhered to the front surface (904B) of the flexible pad (902). In another embodiment of the invention, a human installer may apply a removable/reusable or a permanent adhesive coating onto the mounting apparatus alternatively.

FIGS. 10A-10D show a plate assisted mounting apparatus in accordance with one or more embodiments of the invention. The mounting apparatus (1000) includes a flexible pad (1002) with back and front surfaces (1004A, 1004B) (see e.g., FIGS. 9A-9C). In one embodiment of the invention, the mounting apparatus (1000) may further include a pin perforation (not shown) and a push pin (1008), whereby the pin perforation guides and facilitates the insertion of the push pin (1008) through the flexible pad (1002), and eventually, through the mounting surface (1006) there-behind. In one embodiment of the invention, the push pin (1008) may pierce the flexible pad (1002) and the mounting surface (1006), but not an attachment (e.g., the device mounting plate (1010)) as depicted in FIG. 9C above. In another embodiment of the invention, the push pin (1008) may alternatively be driven through the device mounting plate (1010) as well, thus, further securing the attachment to the mounting surface (1006) whereon an electronic device (1012) may be mounted.

In another embodiment of the invention, the pin perforation (not shown) and push pin (1008) may be excluded. Alternatively, the device mounting plate (1010) may instead be further secured to the mounting surface (1006) by way of fixtures—i.e., a surface fixture (1014) affixed to the mounting surface (1006) wherefrom a plate fixture (1018) is operatively connected using a support line (1016). Furthermore, the plate fixture (1018) may be affixed to the top of the device mounting plate (1010). The surface and plate fixtures (1014, 1018) may be mechanical fasteners that include, but are not limited to including: hooks, brackets, screws, clips, clamps, or any other existing mechanical fasteners. Moreover, the support line (1016) may encompass, for example, a chain, a rope, or wire. In one embodiment of the invention, the device mounting plate (1010) may be supported by multiple fixture sets.

In one embodiment of the invention, an electronic device (1012) may be any physical system incorporating at least an interactive display, a processor, local persistent storage, and volatile memory. Examples of an electronic device (1012) include, but are not limited to including: a reflective display device, an interactive whiteboard, an electronic tablet, an e-flipchart apparatus, or any other interactive device capable of receiving input and presenting information.

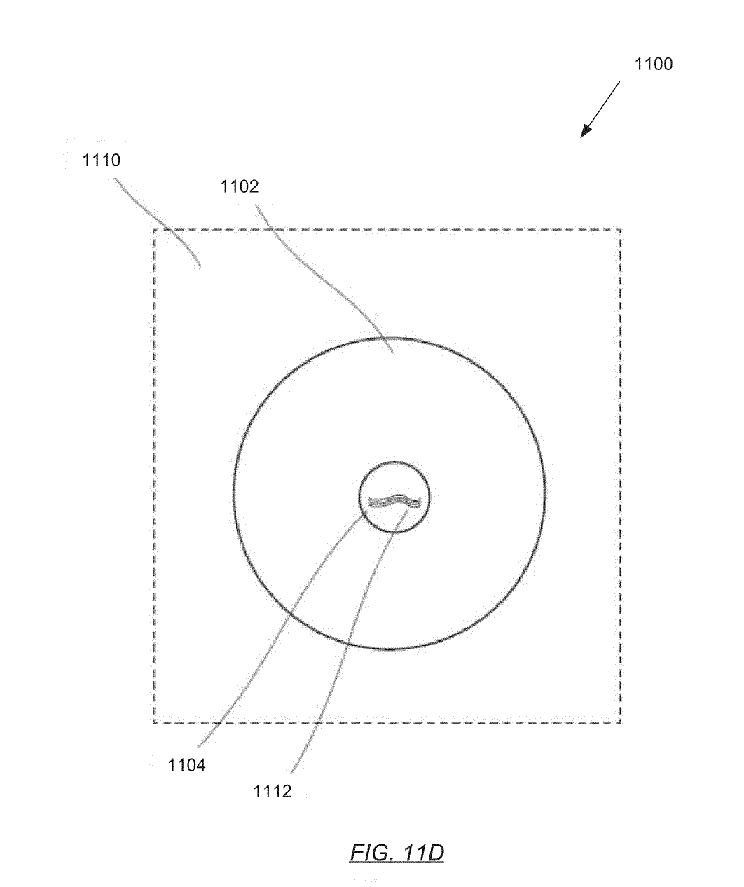

FIGS. 11A-11D show side and front views of a hollow pin assisted mounting apparatus in accordance with one or more embodiments of the invention. The mounting apparatus (1100) includes a gel pad (1102) lined onto the back surface of a flexible pad (1108). The gel pad (1102) may be coated with an adhesive, which may be temporary or permanent. The gel pad (1102) may further secure the flexible pad (1108), and subsequently, the mounting apparatus (1100) to a mounting surface (1110). The adhesive associated with the gel pad (1102) may be substantially similar to any adhesives described above.

In one embodiment of the invention, the mounting apparatus (1100) may further include a hollow pin (i.e., which includes the hollow pin back surface (1106) and hollow pin body (1104)). The hollow pin may be metallic (e.g., stainless steel, brass, tin, iron, etc.), plastic (e.g., thermoplastics, thermoset plastics, etc.), or any combination thereof. Furthermore, the hollow pin may, at least in part, protrude through the gel pad (1102) and/or flexible pad (1108) via a pin perforation (not shown). That is, the hollow pin back surface (1106) (or head) may be disposed between the gel pad (1102) and the mounting surface (1110) when the mounting apparatus (1100) is adhered to the mounting surface (1110). The hollow pin body (1104), on the other hand, may protrude through to the front of the mounting apparatus (1100) (see e.g., FIG. 11D), where the hollow pin body (1104) may remain easily accessible to a user.

In one embodiment of the invention, a pulling force (1114) may be exerted on the hollow pin body (1104), thereby causing the gel pad (1102) and/or flexible pad (1108) to deform. Deformation of the gel pad (1102)/flexible pad (1108) may introduce a momentary vacuum bubble (1116) at the interface between the gel pad (1102)/flexible pad (1108) and the mounting surface (1110). Thereafter, a newly created pressure differential between the different ends of the hollow pin body (1104) may trigger an inflow of ambient air (1112) through the hollow pin body (1104). The ambient air (1112) may subsequently deposit within the vacuum bubble (1116), thereby generating an air-filled bubble (1116). The presence of the ambient air (1112) at the interface between the gel pad (1102)/flexible pad (1108) and the mounting surface (1110) may further facilitate the removal of the mounting apparatus (1100) therefrom.

In one embodiment of the invention, the hollow pin may further include one or more hollow pin handles (1118). Each hollow pin handle (1118) may be disposed on the outside surface of the hollow pin body (1104). In a preferred embodiment, the one or more hollow pin handles (1118) may be disposed near the end of the hollow pin body (1104) that is oppositely disposed to the hollow pin back surface (or head) (1106) (see e.g., FIG. 11C). Further, the hollow pin handles (1118) include functionality to provide a point of manipulation of the hollow pin, and subsequently, the mounting apparatus (1100), by a user in order to facilitate removal. Moreover, the hollow pin handles (1118) may be made from, for example, metals (e.g., stainless steel, brass, tin, iron, etc.), plastics (e.g., thermoplastics, thermoset plastics, etc.), rubbers (e.g., silicone, neoprene, ethylene propylene diene monomer (EPDM), other natural and/or synthetic elastomers, etc.), any high-friction coefficient materials, or any combination thereof

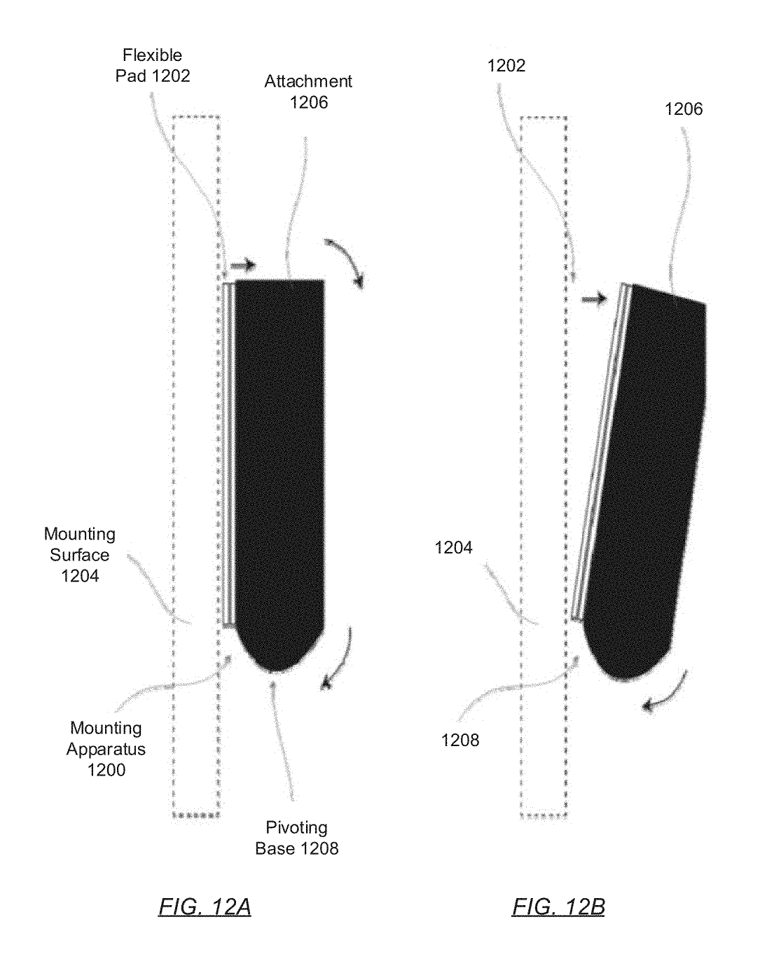

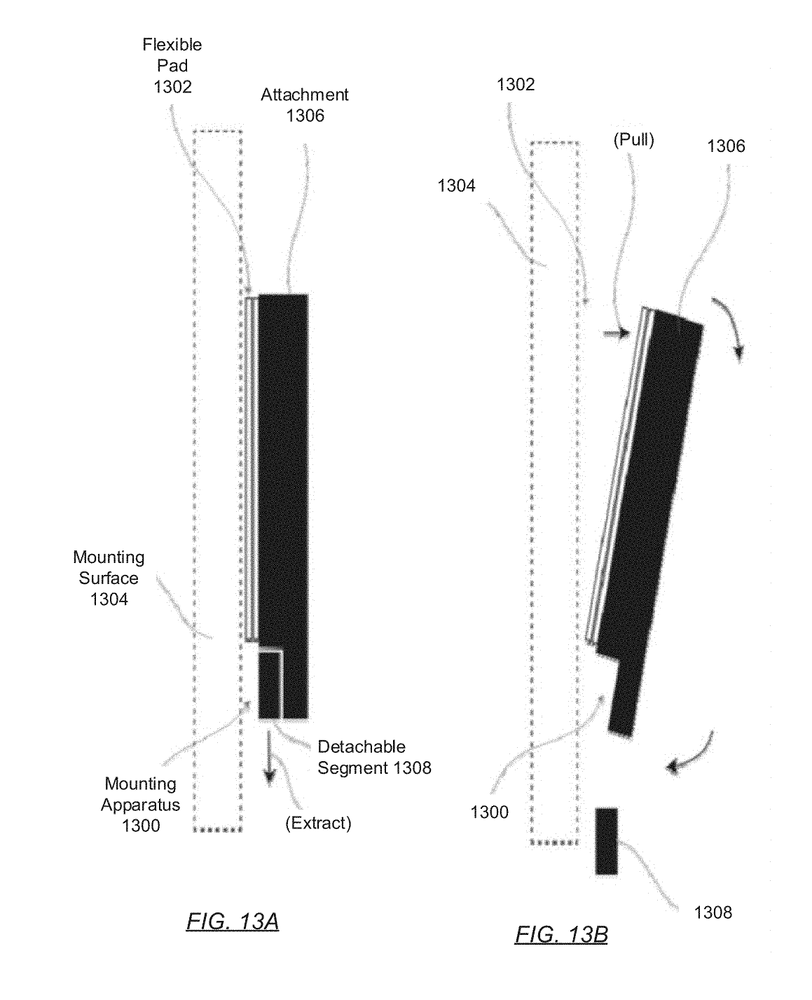

FIGS. 12A and 12B show a pivoting mounting apparatus in accordance with one or more embodiments of the invention. The mounting apparatus (1200) includes a flexible pad (1202) with back and front surfaces (not shown). The back surface of the flexible pad (1202) may be coated with a temporary or permanent adhesive, thereby enabling the adherence of the mounting apparatus (1200) to a mounting surface (1204). Further, the front surface of the flexible pad (1202) may be coated with just a temporary adhesive, whereon an attachment (1206) (described above) (e.g., a device mounting plate (see e.g., FIGS. 10A-10D)) may be affixed temporarily. In one embodiment of the invention, the attachment (1206) may include a pivoting base (1208). The pivoting base (1208) may facilitate the detaching of the mounting apparatus (1200) from the mounting surface (1204).

FIGS. 13A and 13B show a pivoting mounting apparatus in accordance with one or more embodiments of the invention. The mounting apparatus (1300) may be substantially similar to the mounting apparatus depicted in FIGS. 12A and 12B, with the exception that the mounting apparatus (1300) hereafter may additionally include an attachment (1306) with a detachable segment (1308). The detachable segment (1308), when extracted, may facilitate the detaching of the mounting apparatus (1300) from the mounting surface (1304).

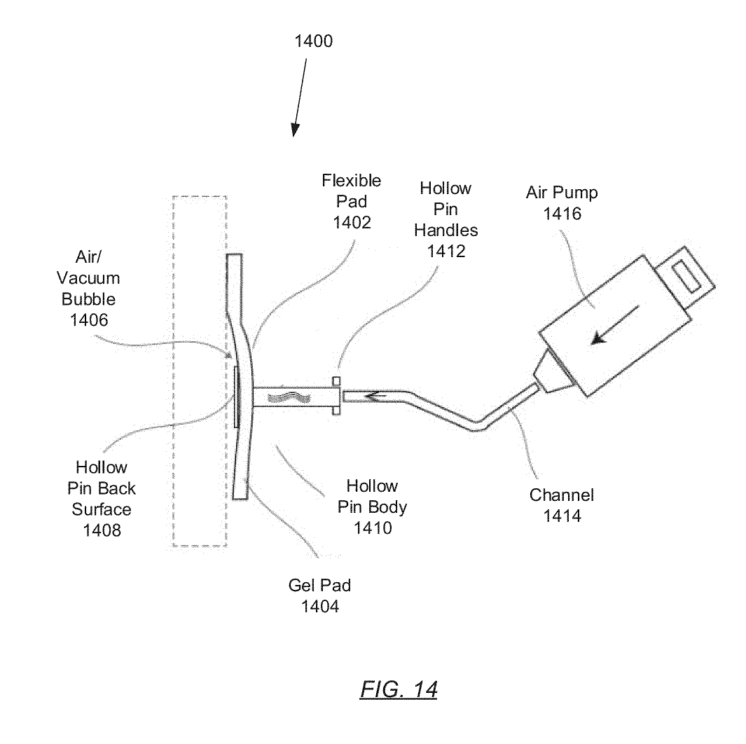

FIG. 14 shows an air injected removal mechanism in accordance with one or more embodiments of the invention. Specifically, rather than requiring the exertion of a pulling force (see e.g., FIGS. 3A and 3B) to induce the formation of a bubble at the interface between the flexible pad (1402) and the mounting surface, air may be injected, via the hollow pin (i.e., hollow pin body (1410)) of a mounting apparatus (1400), to form the bubble. The injected air may be introduced, for example, by way of an air pump (1416), which may be mechanically coupled, directly or indirectly, to an outer end of the hollow pin body (1410). In embodiments whereby the air pump (1416) is indirectly coupled to the hollow pin body (1410), a channel (1414) may be disposed between the outer end of the hollow pin body (1410) and the air pump (1416).

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A mounting apparatus, comprising:
a flexible pad comprising a back surface coated with a removable and reusable adhesive and a front surface;
a backing patch affixed to the front surface of the flexible pad; and
a coupler affixed to and extending outwardly from the backing patch.

2. The mounting apparatus of claim 1, wherein a bubble forms upon an exertion of a force on the coupler that exceeds a size-to-weight ratio rated for the removable and reusable adhesive, wherein the bubble forms at an interface between the back surface of the flexible pad and a mounting surface to which the mounting apparatus is adhered.

3. The mounting apparatus of claim 1, wherein the coupler is one selected from a group consisting of a hook, a plug, a bracket, a pin, and a magnet.

4. The mounting apparatus of claim 1, wherein the flexible pad further comprises a pin perforation.

5. The mounting apparatus of claim 4, further comprising:
a push pin configured to pierce through the flexible pad at the pin perforation, wherein the push pin comprises a flat-blade push pin anchor.

6. The mounting apparatus of claim 5, wherein a bubble forms upon an exertion of a force withdrawing the push pin at a first orientation perpendicular to a second orientation at which the push pin had pierced the flexible pad, wherein the bubble forms at an interface between the back surface of the flexible pad and a mounting surface to which the mounting apparatus is adhered.

7. The mounting apparatus of claim 1, wherein the coupler comprises a plurality of coupler clip cavities along a length of the coupler, wherein the coupler is configured to receive a coupler clip at any coupler clip cavity of the plurality of coupler clip cavities.

8. The mounting apparatus of claim 7, further comprising:
a device mounting plate comprising at least one through-hole,
wherein the coupler is designed to pass through the at least one through-hole,
wherein the device mounting plate is secured thereafter by fastening the coupler clip through a coupler clip cavity along the length of the coupler.

9. A mounting apparatus, comprising:
a flexible pad comprising a pin perforation and an adhesive gel pad disposed on a back surface of the flexible pad; and
a hollow pin configured to pierce through the flexible pad at the pin perforation.

10. The mounting apparatus of claim 9, wherein the hollow pin comprises a hollow pin back surface affixed to an inner end of a hollow pin body, wherein the hollow pin back surface is disposed behind the flexible pad and the hollow pin body is hollow.

11. The mounting apparatus of claim 10, wherein the hollow pin further comprises at least one hollow pin handle disposed on an outer end of the hollow pin body, wherein the outer end and the inner end are oppositely disposed from one another.

12. The mounting apparatus of claim 11, wherein the hollow pin is further configured to facilitate the inflow of air from the outer end of the hollow pin body to the inner end of the hollow pin body.

13. The mounting apparatus of claim 11, wherein the at least one hollow pin handle is configured to facilitate an exertion of a pulling force on the hollow pin by a user.

14. A system, comprising:
an electronic device; and
at least one mounting apparatus operatively connected to the electronic device, and comprising:
a flexible pad comprising a back surface coated with a removable and reusable adhesive, and a front surface coated with a permanent adhesive.

15. The system of claim 14, wherein the at least one mounting apparatus further comprises a device mounting plate disposed between the front surface of the flexible pad and a back surface of the electronic device.

16. The system of claim 15, wherein the at least one mounting apparatus further comprises a plate fixture fastened to a top of the device mounting plate, wherein the plate fixture is secured to a surface fixture via a support line, wherein the surface fixture is fastened to a mounting surface to which the back surface of the flexible pad is adhered.

17. The system of claim 15, wherein the at least one mounting apparatus further comprises a push pin configured to pierce through the device mounting plate, the flexible pad, and a mounting surface to which the back surface of the flexible pad is adhered.

18. The system of claim 14, wherein the at least one mounting apparatus further comprises a pin perforation, and a push pin configured to pierce the flexible pad at the pin perforation, wherein the electronic device is affixed to the front surface of the flexible pad, over the push pin.
